(19) United States
(12) Patent Application Publication
(10) Pub. No.: US 2026/0279727 A1
(43) Pub. Date: Sep. 17, 2026

(54) Matchless RF Plasma Systems for Capacitively Coupled Plasmas

(71) Applicant: Eagle Harbor Technologies, Inc., Seattle, WA (US)

(72) Inventors: James R. Prager, Seattle, WA (US); Kenneth E. Miller, Seattle, WA (US); Timothy M. Ziemba, Bainbridge Island, WA (US); Paul Melnik, Seattle, WA (US)

(73) Assignee: Eagle Harbor Technologies, Inc., Seattle, WA (US)

(21) Appl. No.: 19/678,118

(22) Filed: May 14, 2026

Related U.S. Application Data
(63) Continuation of application No. 19/344,511, filed on Sep. 29, 2025.
(60) Provisional application No. 63/701,435, filed on Sep. 30, 2024.

(51) Int. Cl. H01J 37/32

(52) U.S. Cl. CPC H01J 37/32128; H01J 37/321; H01J 37/32155; H01J 37/3299; H01J 2237/334

(57) ABSTRACT

A matchless RF generator is disclosed that does not require a matching network (or the like) between the RF generator and the plasma. Plasmas have variable inductance or capacitance value during the plasma life cycle. For example, prior to ignition, the plasma chamber may have a first inductance and/or a first capacitance; during ignition, the plasma chamber may have a second inductance and/or a second capacitance; while the plasma is active, the plasma chamber with the plasma may have a third inductance and/or a third capacitance; and during a change in the plasma density, plasma chemistry, plasma brightness, constituent flow rate, plasma voltage, and plasma electric field the plasma chamber with the plasma may have a fourth inductance and/or fourth capacitance.

### BACKGROUND

Traditional plasma generation systems have a few common components that typically consist of an RF generator with fixed output impedance connected to a cable of matching impedance with the output impedance of the RF generator. The cable is connected to a matching network, which is connected to the plasma source. The defining feature of a traditional matched system is that the system works with cables of nearly any length and the matching network matches the plasma impedance to the relatively fixed cable and RF generator output impedance.

### SUMMARY

A matchless RF generator is disclosed that does not require a matching network (or the like) between the RF generator and the plasma. The matchless RF generator, for example, may include an inductive plasma chamber having a plasma inductance and a chamber resistance; an RF generator comprising a plurality of switches that is directly coupled with the inductive plasma chamber, the RF generator produces a voltage waveform to the inductive plasma chamber at a frequency that is substantially similar to a resonant frequency; a resonant capacitor electrically coupled with the RF generator and the inductive plasma chamber, the resonant capacitor having a resonant capacitance; and a controller electrically coupled with the plurality of switches and configured to control the operation of the switches to produce the voltage waveform. In some aspects, the resonant frequency is a function of the plasma inductance, the chamber resistance, and resonant capacitance. In some aspects, the voltage waveform produces an RF waveform at the plasma chamber having an RF waveform amplitude and RF frequency that is the resonant frequency.

In some aspects, the techniques described in this document relate to a method, wherein sensing a change in characteristics of the plasma changer includes sensing a change in an impedance of the plasma chamber.

In some aspects, the techniques described in this document relate to a plasma system, wherein RF waveform amplitude is greater than about 1 kV and the resonant frequency is between about 10 kHz and 100 MHz,

In some aspects, the techniques described in this document relate to the plasma system according to any of the proceeding aspects, wherein the switches are arranged in a full-bridge configuration.

In some aspects, the techniques described in this document relate to a plasma system, wherein the plurality of switches are turned off and on out of phase.

In some aspects, the techniques described in this document relate to the plasma system according to any of the proceeding aspects, wherein the RF generator is directly coupled with the inductive plasma chamber without a 50 ohm matching network.

In some aspects, the techniques described in this document relate to the plasma system according to any of the proceeding aspects, wherein the RF generator is directly coupled with the inductive plasma chamber without a matching network.

In some aspects, the techniques described in this document relate to the plasma system according to any of the proceeding aspects, wherein the RF frequency is between about 10 kHz and 100 MHz and an RF waveform amplitude greater than 100 volts.

In some aspects, the techniques described in this document relate to the plasma system according to any of the proceeding aspects, wherein the plasma inductance is less than about 1 nH to 10 mH.

In some aspects, the techniques described in this document relate to the plasma system according to any of the proceeding aspects, wherein the RF frequency changes to a different RF frequency in less than 0.1 to 100 periods.

In some aspects, the techniques described in this document relate to the plasma system according to any of the proceeding aspects, wherein the RF frequency changes in response to one or more changes in one or more of the following: a plasma density, plasma chemistry, plasma brightness, constituent flow rate, plasma voltage, and plasma electric field.

In some aspects, the techniques described in this document relate to the plasma system according to any of the proceeding aspects, wherein the RF frequency changes to ensure one or more changes in one or more of the following: a constant plasma density, a constant plasma chemistry, a constant plasma brightness, a constant constituent flow rate, or a constant plasma voltage, constant power into the chamber, and a constant plasma electric field.

In some aspects, the techniques described in this document relate to the plasma system according to any of the proceeding aspects, wherein the RF generator can change an output frequency in less than 10 ms.

In some aspects, the techniques described in this document relate to the plasma system according to any of the proceeding aspects, wherein RF frequency changes to a different frequency in less than 100 μs.

In some aspects, the techniques described in this document relate to the plasma system according to any of the proceeding aspects, wherein the RF generators produces an average peak power between 10 W and 500 kW.

In some aspects, the techniques described in this document relate to the plasma system according to any of the proceeding aspects, wherein the output power of the RF generator changes in less than 100 μs.

In some aspects, the techniques described in this document relate to the plasma system according to any of the proceeding aspects, wherein the RF generator produces bursts of RF signals at a frequency of 1 Hz-1 MHz.

In some aspects, the techniques described in this document relate to the plasma system according to any of the proceeding aspects, wherein the RF waveform includes a plurality of RF burst waveforms of longer than 10 μs.

In some aspects, the techniques described in this document relate to a plasma system, wherein the average power of an RF burst waveform is between 500 W-1 MW.

In some aspects, the techniques described in this document relate to a plasma system, wherein the average continuous power of an RF burst waveform is between 5 W-50 kW.

In some aspects, the techniques described in this document relate to a plasma system, wherein the RF generator changes a burst power, average power, and/or burst duty cycle in response to one or more changes in plasma density, plasma chemistry, plasma brightness, constituent flow rate, plasma voltage, and/or plasma electric field.

In some aspects, the techniques described in this document relate to a plasma system, wherein the plurality of RF burst waveforms includes a first RF burst waveform a second plurality of RF burst waveforms, wherein the first RF burst waveform has a greater peak power than the second plurality of RF burst waveforms.

In some aspects, the techniques described in this document relate to the plasma system according to any of the proceeding aspects, wherein the plurality of RF burst waveforms includes a first RF burst waveform a second plurality of RF burst waveforms, wherein the first RF burst waveform has a substantially higher voltage than the second plurality of RF burst waveforms.

In some aspects, the techniques described in this document relate to the plasma system according to any of the proceeding aspects, wherein the RF generator produces a plasma with a desired plasma density in less than about 10 μs.

In some aspects, the techniques described in this document relate to the plasma system according to any of the proceeding aspects, wherein the RF generator operates at a first frequency, a first power, and/or a first voltage to produce a plasma with a first set of reactance species; wherein the RF generator operates at a second frequency, a second power, and/or a second voltage to produce a plasma with a second set of reactance species; wherein the first reactance species and the second reactance species are different and are selected from the group consisting of F, O, N, Ar, B, Si, Cl, and C, and any radicals selected from the group consisting of Si02, SiF4, NF3, and CH4; wherein the first frequency and the second frequency are different; wherein the first voltage and the second voltage are different; and wherein the first power and the second power are different.

In some aspects, the techniques described in this document relate to the plasma system according to any of the proceeding aspects, wherein the RF generator operates at a first frequency, a first power, and/or a first voltage to produce a plasma with a first set of reactance species from one or more molecular combinations; wherein the RF generator operates at a second frequency, a second power, and/or a second voltage to produce a plasma with a second set of reactance species from one or more molecular combinations; wherein the molecular combinations are selected from the group consisting of Si02, SiF4, NF3, and CH4; wherein the first frequency and the second frequency are different; wherein the first voltage and the second voltage are different; and wherein the first power and the second power are different.

In some aspects, the techniques described in this document relate to the plasma system according to any of the proceeding aspects, wherein the RF generator converts CH4 to H2 and C.

In some aspects, the techniques described in this document relate to the plasma system according to any of the proceeding aspects, wherein the RF generator converts Si to SiF4.

In some aspects, the techniques described in this document relate to the plasma system according to any of the proceeding aspects, wherein the RF generator produces NH3.

In some aspects, the techniques described in this document relate to the plasma system according to any of the proceeding aspects, further including a DC source; wherein the RF generator and the DC source alternate producing bursts into the plasma.

In some aspects, the techniques described in this document relate to a matchless RF system, wherein the RF generator bursts occur for a period of about 1 ms and the DC bursts occur for a period of about 1 ms.

In some aspects, the techniques described in this document relate to a matchless RF system 29-30, wherein the RF generator and the DC source alternate producing bursts into the plasma to maintain a substantially uniform IEDF.

In some aspects, the techniques described in this document relate to a matchless RF system 29-31, wherein the RF generator and the DC source alternate producing bursts into the plasma to optimize and/or control one or more of the following parameters etch rate, bow growth rate, feature diameter, hole aspect ratio, mask erosion rate, and cd.

In some aspects, the techniques described in this document relate to a matchless RF system 29-32, wherein between each RF burst the RF generator produces waveforms with lower but greater than zero voltage, power, and/or frequencies.

In some aspects, the techniques described in this document relate to a matchless RF system 29-33, wherein in between each DC burst the DC source produces waveforms with lower but not zero voltage or power.

In some aspects, the techniques described in this document relate to a method for producing an RF waveform produced with a full-bridge circuit including a first switch, a second switch, a third switch, and a fourth switch, the method including: in a first phase, closing the first switch and the fourth switch while keeping the second switch open and the third switch open; pausing for a first period of time; in a second phase, keeping the first switch closed while opening the fourth switch and while keeping the second switch open and the third switch open; pausing for a second period of time; in third phase, keeping the first switch closed while closing the third switch and while keeping the second switch open and the fourth switch open; pausing for a third period of time; in a fourth phase, opening the first switch while keeping the third switch closed and while keeping the second switch open and the fourth switch open; pausing for a fourth period of time; in a fifth phase, closing the second switch while keeping the third switch closed and while keeling the first switch open and the fourth switch open; pausing for a fifth period of time; in a sixth phase, opening the third switch while keeping the second switch closed and while keeling the first switch open and the fourth switch open; pausing for a sixth period of time; in a seventh phase, closing the fourth switch while keeping the second switch closed and while keeling the first switch open and the third switch open; pausing for a seventh period of time; in an eighth phase, opening the second switch while keeping the fourth switch closed and while keeling the first switch open and the third switch open; pausing for an eighth period of time; and outputting an RF waveform.

In some aspects, the techniques described in this document relate to a method, wherein each of the second period of time, the fourth period of time, the sixth period of time, and the eight period of time are less than each of the first period of time, the third period of time, the fifth period of time, and the seventh period of time.

In some aspects, the techniques described in this document relate to a method for controlling an amplitude of an RF waveform produced with a full-bridge circuit including a first switch, a second switch, a third switch, and a fourth switch, the method including: opening and closing the first switch and the fourth switch with a temporal phase shift and with a first frequency, wherein the first switch and the fourth switch are closed for a first period of time while the second switch and the third switch are open; opening and closing the second switch and the third switch with a temporal phase shift and the with the first frequency, wherein the second switch and the third switch are closed for the first period of time while the first switch and the fourth switch are open; and outputting an RF waveform having a frequency that is the same as the first frequency and having an amplitude that is a function of the first period of time.

In some aspects, the techniques described in this document relate to a method, further including changing the duration of the first period of time; and outputting a second RF waveform having a frequency that is the same as the switch frequency and having an amplitude that is a function of the changed first period of time.

In some aspects, the techniques described in this document relate to a method, further including changing the switch frequency to a second frequency; and outputting a third RF waveform having a frequency that is the same as the second frequency and having an amplitude that is a function of the changed first period of time.

In some aspects, the techniques described in this document relate to a method for controlling an amplitude of an RF waveform produced with a full-bridge circuit including a first switch, a second switch, a third switch, and a fourth switch, the method including: opening and closing the first switch, the second switch, the third switch, and the fourth switch with a first switch duty cycle and a first switch frequency; outputting a first RF waveform having a first RF frequency and a first RF amplitude into a plasma chamber; sensing a change in characteristics of the plasma; opening and closing the first switch, the second switch, the third switch, and the fourth switch with a second switch duty cycle and a second switch frequency, wherein the second duty cycle is different than the first switch duty cycle and wherein the first switch frequency is different than the second switch frequency; outputting a second RF waveform having a second RF frequency and a second RF amplitude into the plasma chamber, wherein either or both the second RF frequency and the second RF amplitude are different from the first RF frequency and the first RF amplitude.

In some aspects, the techniques described in this document relate to a method, wherein sensing a change in characteristics of the plasma changer includes sensing a change in one or more of the following: a plasma density, plasma chemistry, plasma brightness, constituent flow rate, plasma voltage, and plasma electric field.

In some aspects, the techniques described in this document relate to a method, wherein sensing a change in characteristics of the plasma changer includes sensing a change in an impedance of the plasma chamber.

### BRIEF DESCRIPTION OF THE FIGURES

FIG. 1 shows a matchless RF generator.

FIG. 2A shows an example of a capacitive plasma system.

FIG. 2B shows an example of an inductive plasma system.

FIG. 3A illustrates an example insulated capacitive plasma system.

FIG. 3B and an example insulated inductive plasma system.

FIG. 4 is a circuit diagram of an example matchless RF generator.

FIG. 5 is a flow chart showing a process for phase shift control.

FIG. 6 shows control logic for each of the switches in phase shift control.

FIGS. 7-14B show the flow of current through the matchless RF generator shown in FIG. 4 during each phase of a for phase control process.

FIG. 15A and FIG. 15B show pulse width modulation to produce output pulses with lower or higher amplitudes.

FIG. 16 is a circuit diagram of an example matchless RF generator with a transformer.

FIG. 17 is a flowchart of an example process for producing an RF waveform with a matchless RF generator.

FIG. 18 is a flowchart of an example process for producing an RF waveform with a matchless RF generator.

FIG. 19 shows control logic for each of the switches in phase shift control.

FIG. 20 is a block diagram of a controller that can be used to with or to perform some embodiments described in this document.

### DETAILED DESCRIPTION

A matchless RF generator is disclosed that does not require a matching network (or the like) between the RF generator and the plasma. Plasmas have variable inductance and/or capacitance and/or impedance value during the plasma life cycle. For example, prior to ignition, the plasma chamber may have a first inductance and/or a first capacitance and/or a first impedance; during ignition, the plasma chamber may have a second inductance and/or a second capacitance and/or a second impedance; while the plasma is active, the plasma chamber with the plasma may have a third inductance and/or a third capacitance and/or a third impedance; and during a change in the plasma density, plasma chemistry, plasma composition, plasma brightness, constituent flow rate, plasma voltage, and/or plasma electric field the plasma chamber with the plasma may have a fourth inductance and/or fourth capacitance and/or a fourth impedance.

A plasma may have properties that vary in time over timescales that may span from the nanosecond hours. For example, plasma formation may occur in timescales between 1 ns and 100 microsecond and plasma relaxation may occur on timescales between 1 microsecond and 1 second. Plasma process requirements may require and/or cause adjustments on the 1 millisecond to 10 minute timescales. Various other properties of a plasma may have different timescales. Plasmas may be very dynamic, some embodiments described in this document may address this variability across a wide range of timescales. The above timescales are given for example only, and there are many other envisioned timescales of relevance.

Moreover, the power requirements may change during the plasma life cycle. For example, more power may be needed during ignition than during other portions of the plasma life cycle. For example, the power required during plasma ignition may range between 2 times greater and 100,000 times greater than the power required during plasma sustainment. As another example, the voltage required for plasma ignition may deviate significantly from the voltage needed during plasma sustainment. Voltages for plasma ignition may range from about 100 V to about 100,000 V, while voltages needed during plasma sustainment may range from about 50 V to about 5,000 V.

To maintain a constant RF frequency, voltage, impedance, and/or power at the output of a driving power supply (e.g., RF generator) a matching network that is positioned between a plasma generator (e.g., an RF generator, or RF power supply, or driving power supply) and the plasma chamber has been required. A matching network, for example, can adjust the impedance of the plasma as seen by the output of the RF generator to match the output impedance of the RF generator. Such adjustments are typically made on the timescales required to mechanically set variable capacitors and/or inductors. These timescales are often longer than the timescales of variable properties of the plasma. The examples described in this document do not require a matching network.

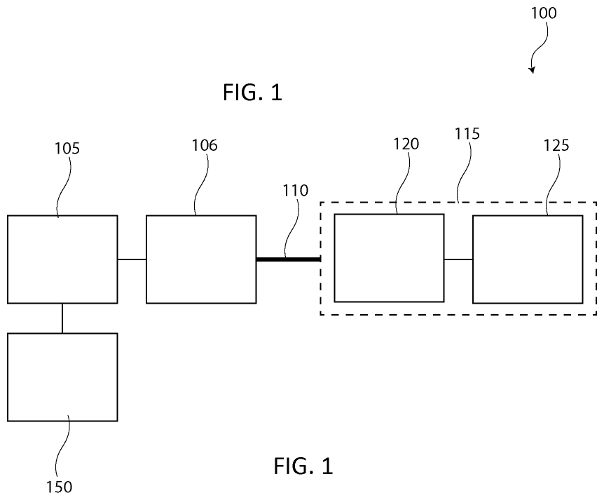

FIG. 1 is a block diagram of a matchless RF generator 100. The matchless RF generator 100, for example, can drive a wide range of output impedances.

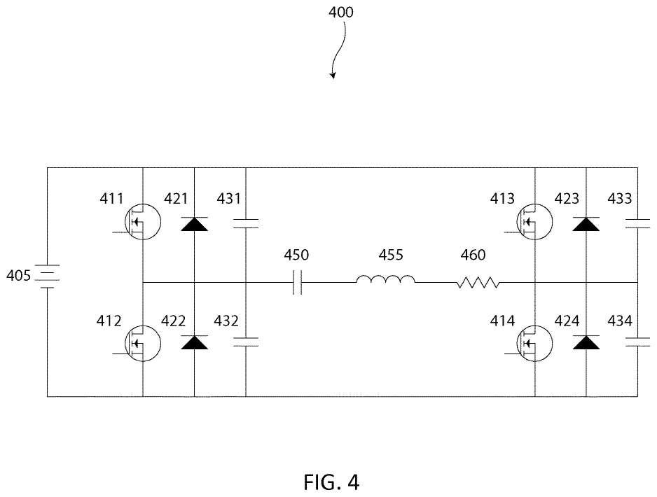

The matchless RF generator 100 includes a plurality of switches 105. The Plurality of switches 105 may include any number of switches in any arrangements such as, for example, a full bridge switching circuit (e.g., as shown in FIG. 4), a half bridge switching circuit, or any bridge driving circuit.

The output of the Plurality of switches 105, for example, may have floating ground. The output of the Plurality of switches 105, for example, may have a fixed ground.

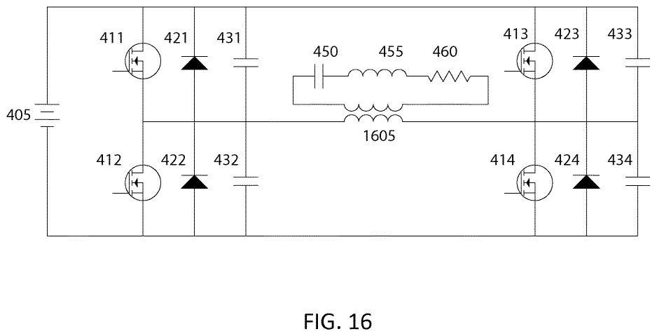

The Plurality of switches 105, for example, may or may not include or be coupled with a transformer 106 (e.g., as shown in FIG. 16). The transformer may be a single transformer or a composite of multiple transformers.

The Plurality of switches 105, for example, may produce RF waveforms with a frequency between about 100 kHz and about 65 MHz. For example, the Plurality of switches 105 may produce RF waveforms with a frequency of about 400 kHz, 13.56 MHz, and 27 MHz. The Plurality of switches 105, for example, may adjust its frequency about its nominal frequency, by as much as +/−1%, +/−10%, or +/−20%. Frequency adjustment may be done to maintain specific plasma conditions and/or to maintain specific power or voltage delivery requirements to the plasma.

Frequency adjustments may be made on a variety of timescales. Typical timescales of adjustment may range from 10 microseconds to 10 seconds. A frequency adjustment may be made in conjunction with a feedback and control system 150, and may be done at a frequency as set by the control system. Frequency adjustments may be made continuously or in discrete steps.

The matchless RF generator 100, for example, may also include one or more resonant elements 115. The Plurality of switches 105 and/or the transformer 106 for example, may be coupled with the one or more resonant elements 115 via a cable 110. The cable 110, for example, may also have a capacitance, inductance, and/or resistance.

The cable 110, for example, may be shorter than about 1 m or 0.5 m. The length of the cable, for example, may be short compared to the wavelength of the frequency of operation. Thus, for example, at lower frequencies, longer cables may be used and at higher frequencies. Shorter cables may be used. The cable 110, for example, can be treated as a lumped element circuit component with a characteristic capacitance, inductance, and/or resistance. The cable 110, for example, may be short enough that its natural capacitance, inductance, and/or resistance may be small compared to some of the resonant elements 115. The impedance of the cable 110 may be less than the effective impedance of the resonant elements 115.

For example, one or more resonant elements 115 may include a series resonant circuit as shown in FIG. 1. In this example, a capacitive resonant element 120 may be coupled in series, either physically or as an effective circuit, with an inductive resonant element 125.

As another example, the one or more resonant elements 115 may include resonant elements arranged in parallel. In this example, a capacitive resonant element 120 may be coupled in parallel, either physically or as an effective circuit, with an inductive resonant element 125.

Resonant elements 115, for example, may contain any number of resonant elements arranged in any particular manner. For example, resonant elements 115 may contain a series inductor and capacitor, with another capacitor placed in parallel with the plasma load. The specific resonant elements, for example, may be selected to establish, for example, a specific power transfer to the plasma, and/or to establish a specific voltage across the plasma. They may be selected to create a resonant circuit with a specific desired quality factor Q.

The resonant elements 115, for example, may be selected to control the impact the plasma has on the specific resonant frequency. For example, some combination of inductors and capacitors may be selected to limit the plasma's perturbation of the circuits natural resonant frequency to less than 1%, less than 5%, or less than 25%. The specific resonant elements selected may include any combination of capacitors and inductors placed in series and/or in parallel. Alternately, only a single capacitor or single inductor may be selected.

Alternatively or additionally, any number of resonant elements may be tied to ground, or none may be tied to ground. Any number of resonant elements may be tied to the plasma creating elements, or only one may be tied to the plasma creating elements. In an inductively coupled plasma (ICP), for example, the plasma creating element will be an antenna dominantly characterized by its inductance. In a capacitively coupled plasma (CCP), for example, the plasma creating element will likely be an antenna dominantly characterized by its capacitance. Numerous other plasma creating elements are envisioned that may contain best be represented by any general combination of inductances and/or capacitances, and/or resistances, where some of the elements may best be represented as if they were coupled through a transformer.

One or more resonant elements 115 may include a capacitive plasma chamber, a capacitive plasma chamber with a plasma, an inductive plasma chamber, or an inductive plasma chamber with a plasma.

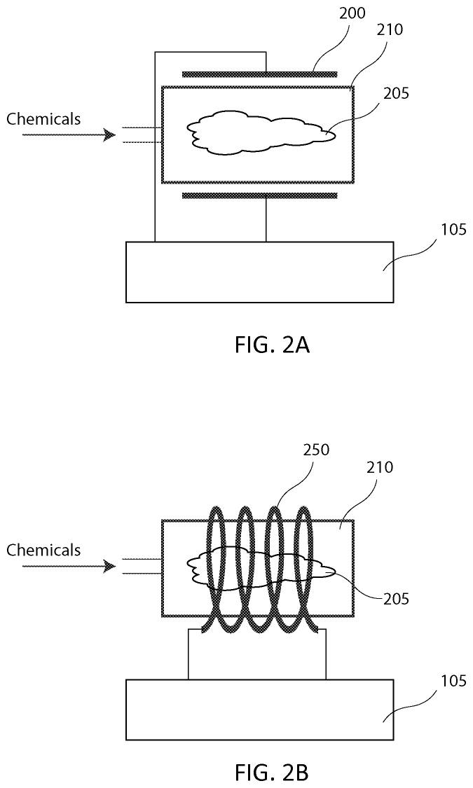

At least one of the one or more resonant elements 115 may be coupled with a plasma. FIG. 2A shows a capacitive resonant element 200 coupled with a plasma chamber 210 within which a plasma 225 may be formed. The capacitive resonant element 200, for example, may have a capacitance of about 1 pF to 100 mF. The capacitive resonant element 200 may be electrically coupled with a Plurality of switches 105. The capacitive resonant element 200, for example, may be electrically coupled with a transformer 106, and/or with resonant elements 115.

The matchless RF generator 100 may include a feedback and control subsystem 150. The 150 may include any and all components of controller 2000. The feedback and control system 150 may include various sensors that may be coupled with the capacitive resonant element 120 and/or the inductive resonant element 125. These sensors may, for example, provide the feedback and control system 150 with data regarding the properties of a plasma within a plasma chamber. The feedback and control system 150 may control the operation of the plurality of switches 105 such as, for example, switching frequency, duration, etc. as described in this document.

FIG. 2B shows an inductive resonant element 250 coupled with a plasma chamber 210 within which a plasma 225 may be formed. The inductive resonant element 250, for example, may have an inductance of about 1 nH to 100 mH. The inductive resonant element 250 may be electrically coupled with a plurality of switches 105. The inductive resonant element 200 may be electrically coupled with a transformer 106, and/or with resonant elements 115.

The inductive resonant element 250 can include any type of inductively coupled plasma. The inductive resonant element 250, for example, may be a plasma source where the energy is supplied by electric currents which are produced by electromagnetic induction by time-varying magnetic fields. For example, the inductive resonant element 250 may include a wire wrapped around an insulating tube that contains the plasma. The plasma 225 may be formed, for example, when a time varying magnetic field, driven by the Plurality of switches 105, ionizes atoms within the inductive resonant element 250.

The capacitive resonant element 200, for example, may include capacitive electrodes within an insulator. The plasma 225 may be formed, for example, when an electric field is created between the capacitive electrodes, driven by the Plurality of switches 105, which ionizes atoms within the capacitive resonant element 200.

The insulating material in either the capacitive resonant element 200 or the inductive resonant element 250, for example, may include silica, alumina, AlN, SiC, or BeO. As another example, the insulating material may include any type of ceramic and/or plastic polymer. Numerous combinations of various ceramics and/or polymers may be used, as may any material that allows electric and or magnetic fields to partially or fully penetrate it. Various conductors may be arranged within or about the ceramics used to facilitate plasma ignition and/or sustainment, and/or to create or shape specific regions of electric and/or magnetic field.

FIGS. 2A and 2B shows the plasma existing within a chamber. The plasma may exist within a chamber having any shape.

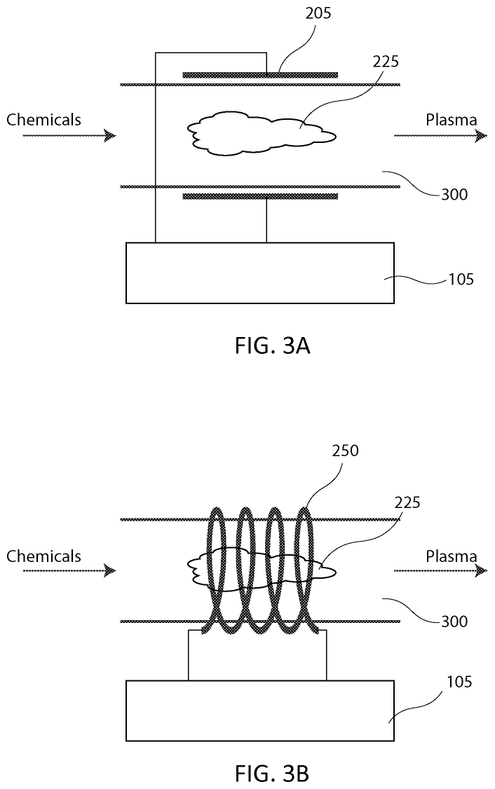

FIG. 3A shows a capacitive resonant element 205 coupled with a plasma tube 300 within which a plasma 225 may be formed. The capacitive resonant element 205, for example, may have a capacitance of about 1 pF to 100 mF. The capacitive resonant element 205 may be electrically coupled with a Plurality of switches 105. The inductive resonant element 200, for example, may be electrically coupled with a transformer 106, and/or with resonant elements 115.

FIG. 3B shows an inductive resonant element 250 coupled with a plasma tube 300 within which a plasma 225 may be formed. The inductive resonant element 250, for example, may have an inductance of about 10 nH to 10 mH. The inductive resonant element 250 may be electrically coupled with a Plurality of switches 105.

The one or more resonant elements 115 may have dimensions from about 1 cm to about 10 m. As another example, the one or more resonant elements 115 may have dimensions from about 5 cm to about 50 cm. Resonant elements of any particular size and/or shape, and/or arrangement of sizes and/or shapes may be selected.

FIG. 4 is an example circuit diagram of a full bridge matchless RF generator 400.

The matchless RF generator 400, for example, may include four switches (or switch modules, where each switch module comprises a plurality of switches). Each switch of the four switches (switch 411, switch 412, switch 413, and switch 413, collectively the “switches”) for example, may each include any number of solid state switches arranged in series or parallel. The switches, for example, may include any type of solid-state switch such as, for example, IGBTs, MOSFETs, SiC MOSFETs, SiC junction transistors, FETs, SiC switches, GaN switches, photoconductive switches, etc. Each switch may include a capacitor and a diode.

The switch 411 may be coupled with a diode 421 and/or capacitor 431 across the switch 411. The switch 412 may be coupled with a diode 422 and/or capacitor 432 across the switch 412. The switch 413 may be coupled with a diode 423 and/or capacitor 433 across the switch 413. The switch 414 may be coupled with a diode 424 and/or capacitor 434 across the switch 411. Each of the diode 421, diode 422, diode 423, and diode 424, for example, may include a single diode or a plurality of diodes. Each of the capacitor 431, capacitor 432, capacitor 433, and capacitor 434, for example, may include a single capacitor or a plurality of capacitors. Additionally or alternatively, the capacitor 431, capacitor 432, capacitor 433, and capacitor 434, for example may represent parasitic capacitances contained within the circuit and/or across the switches.

Parasitic inductances between the various switches, for example, may be less than 1 uH, or 100 nH. The switches may be specifically placed and/or arranged to control and/or minimize the inductance between components.

Parasitic capacitance across the switches may be less than 10 nF or 100 pF, for example. The switches may be specifically placed and/or arranged to control and/or minimize the associated capacitance and/or parasitic capacitance that occurs across them.

The switches may be coupled with power supply 405. The power supply 405 may include a DC or AC power supply. The power supply may include one or more energy storage capacitors. The power supply may include a capacitive source and/or AC-DC converter, etc.

The inductance between power supply 405 and the switches, for example, may be less than 10 uH, 1 uH, or 100 nH. An energy storage capacitor, for example, may be placed in close proximity to the switches in order to minimize and/or control the inductance between the energy storage and the switches.

The effective load and/or actual load of the full-bridge circuit may include capacitance 450, inductance 455, and resistance 460, collectively the load. These components may vary depending on the configuration and/or application. For example, for an inductive plasma the inductance 455 may represent the inductive resonant element of the plasma chamber (e.g., the inductive coil), the inductance of the plasma, and/or the inductance of other circuit elements (e.g., traces, transformer, etc.). The capacitance 450, for example, may represent the capacitance of one or more capacitors that are selected to control the resonance of the circuit, the capacitance of the plasma chamber, and/or the capacitance of other circuit elements (e.g., traces, transformer, etc.). Alternatively or additionally, for a capacitive plasma the capacitance 450 may represent the capacitance of a capacitively coupled plasma chamber and/or the plasma created within the chamber. The resistance 460, for example, may represent the resistance of the plasma, the resistance of a cable between the Matchless RF generator 400 and the plasma chamber, and/or the resistance of other circuit elements (e.g., traces, transformer, etc.).

While capacitance 450, inductance 455, and resistance 460 are arranged in series in FIG. 4, these components may be arranged in series or parallel in any combination of inductors and/or capacitors, and/or resistors is envisioned. A specific arrangement, for example, may be set by the type of plasma being created, the geometry of the chamber, the frequency of operation, and/or specifics of the other portions of the RF Generator 400. Any type of combination is envisioned.

The switches may be communicatively coupled with a controller that controls when the switches are turned off and on via a control signal. The controller, for example, may include any or all the components found in the controller 2000. For example, the duty cycle and/or frequency of each of the switches can be adjusted by changing the duty cycle of control signals. Each switch, for example, can be switched independently or in conjunction with one or more of the other switches. For example, the signal to the switch 411 may be the same signal as signal to the switch 413. As another example, the signal to the switch 412 may be the same signal as the signal to the switch 414. As another example, each signal may be independent and may control each switch independently or separately, for example, as discussed below.

The switches may be switched at high frequencies and/or may produce a high voltage pulses. These frequencies may, for example, include frequencies of about 10 kHz, 400 kHz, 0.5 MHz, 2.0 MHz, 4.0 MHz, 13.56 MHz, 27.12 MHz, 40.68 MHz, 50 MHz, etc. These frequencies, for example, may be greater than 10 kHz. Each switch may or may not include the same number or same type of solid state switches as the other switches.

Multiple diodes may be used per switch, while some switches may have no diode associated with them, while other switches may share a common diode or diodes. The stray inductances of the switches, for example, may be substantially equal. The stray inductances of the switches, for example, may be less than about 10 nH, 50 nH, 100 nH, 150 nH, 500 nH, 1,000 nH, etc. The stray inductance of each switch, for example, may be less than about 200 nH. The stray inductance of each switch, for example, may be between about 100 nH and about 500 nH. The combination of a switch and a respective bridge diode may be coupled in series with a respective bridge inductor.

A matchless RF generator 400, for example, may be operated at the resonant frequency of any or all of the resonant elements in the circuit. As another example, the matchless RF generator may be operated at a frequency above or below the circuits resonant frequency. Where the circuit has multiple resonant frequencies, some set by the selection of specific resonant elements and/or plasma properties and/or plasma geometries, the matchless RF generator may be operated at frequencies above or below any of them. The matchless RF generator 400, for example, may be operated off the resonant frequency to set a specific power or voltage transfer to the plasma, for example.

The matchless RF 400 generator, for example, may be operated off of resonance to realize specific switch performance and/or efficiency.

The matchless RF generator 400 may not include a traditional matching network such as, for example, a 50Ω matching network or an external matching network or standalone matching network. Indeed, the embodiments described within this document do not require a 50Ω matching network to tune the switching power applied to the wafer chamber. In addition, embodiments described within this document provide a variable output impedance RF generator without a traditional matching network. This can allow for rapid changes to the power drawn by the plasma chamber. Typically, for example, this tuning of the matching network can take at least about 100 us to about 200 μs or other times. Power changes, for example, can occur within one or two RF cycles, for example, about 2.5 μs to about 5.0 μs at about 400 KHz.

The matchless RF generator 400, for example, output may be changed by adjusting the duty cycle of the switches. This may, for example, require hard switching. This may not, for example, allow zero voltage switching, which may increase the power that the switches dissipate, limiting high frequency operation.

The switches, for example, may operate at 50% duty cycle (minus deadtime). The signal controlling the switch 411 and the switch 412 may be phased relative to the signals controlling the switch 413 and the switch 414. This may, for example, allow for the output to be adjusted in real time by changing the duty cycle. This may, for example, allow for zero voltage switching and high frequency operation.

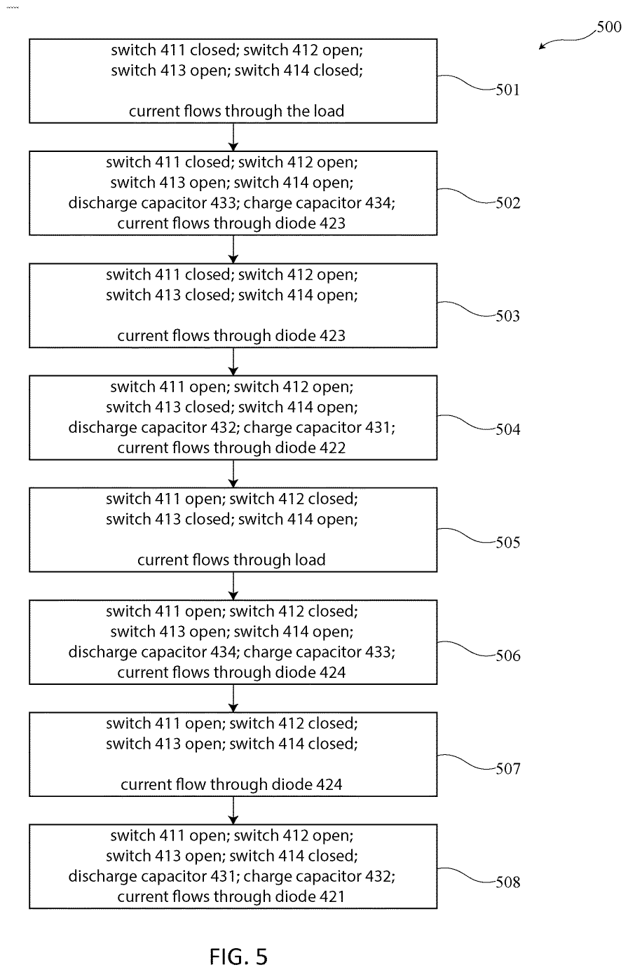

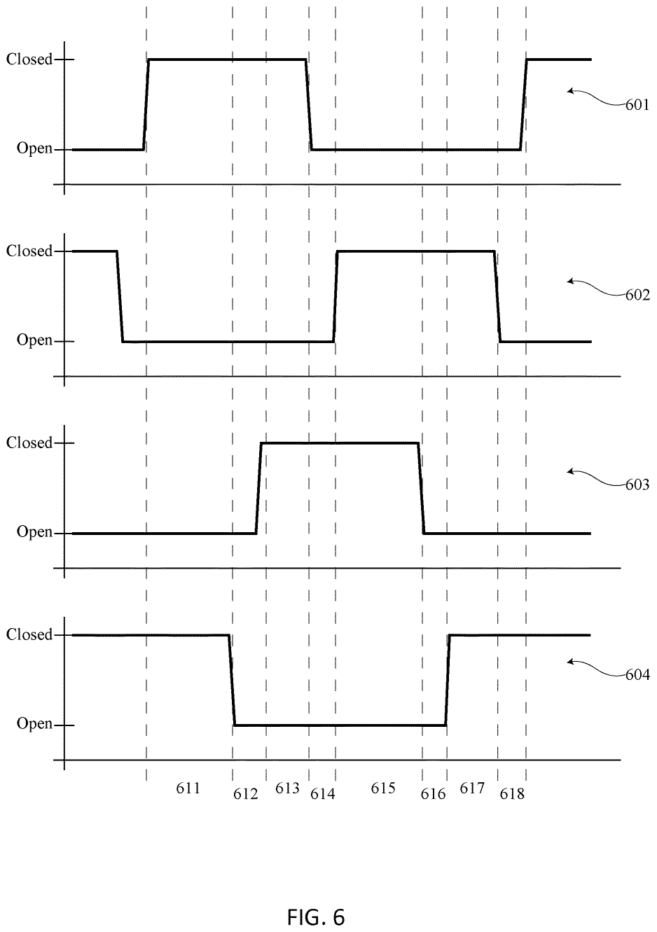

FIG. 5 is a flow chart showing a process 500 for phase shift control of the switches. FIG. 6 shows control logic for each of the switches following the process 500 with control between switches having a phase shift. Waveform 601 represents logic for switch 411, waveform 602 is logic for switch 412, waveform 603 is logic for switch 413, and waveform 604 is logic for switch 414. A switch is closed with the logic is asserted and the switch is closed with the logic is unasserted.

Phase shift control, for example, may allow for fast adjustments to the output power without changing input voltage and/or may maintains zero voltage switching over a wide range of conditions. Zero voltage switching, for example, may reduce switching losses (e.g., switch heating), increase efficiency, and/or reduce EMI. Zero voltage switching, for example, may allow for operation with reduced timing accuracy. Zero voltage switching, for example, may also reduce reverse conduction losses.

FIG. 6 shows control logic of the switches operating with phase control.

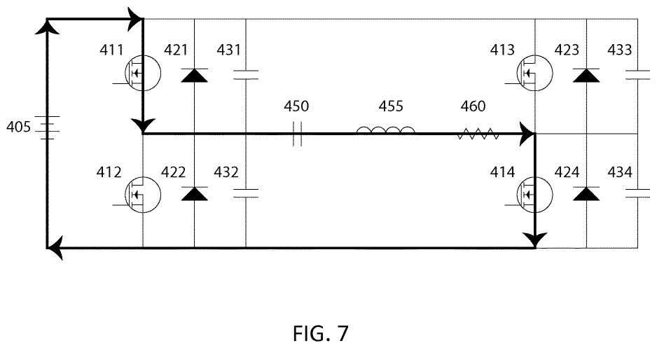

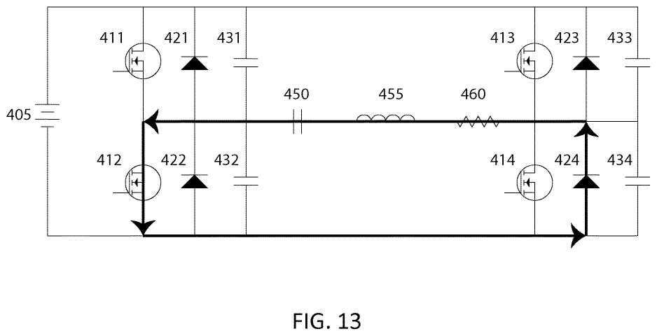

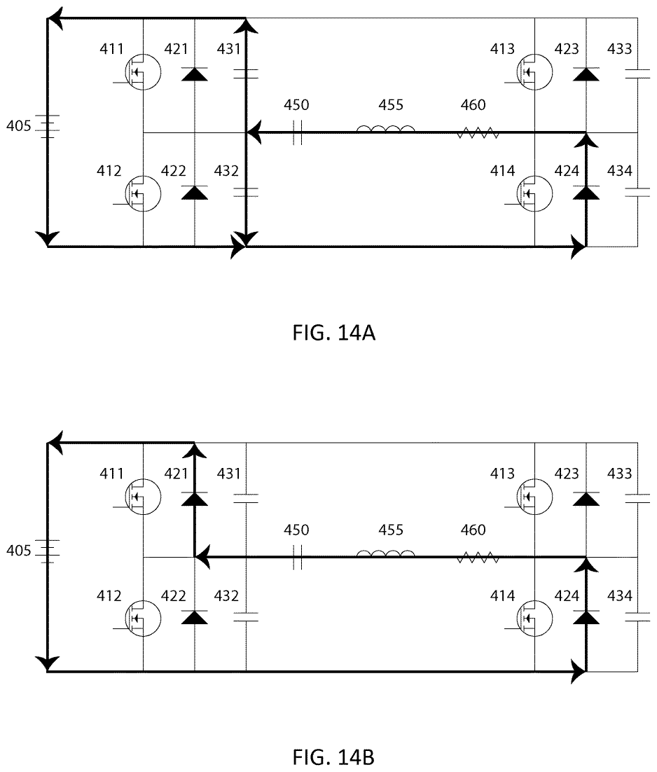

FIGS. 7-14B show the flow of current through the matchless RF generator during each phase of a for phase control process.

At block 501 of process 500, the switches are in the following states: switch 411 is closed, switch 412 is open, switch 413 is closed, and switch 414 is open. During this phase, current flows into the load as shown in FIG. 7. This is shown in FIG. 6 as the time period 611.

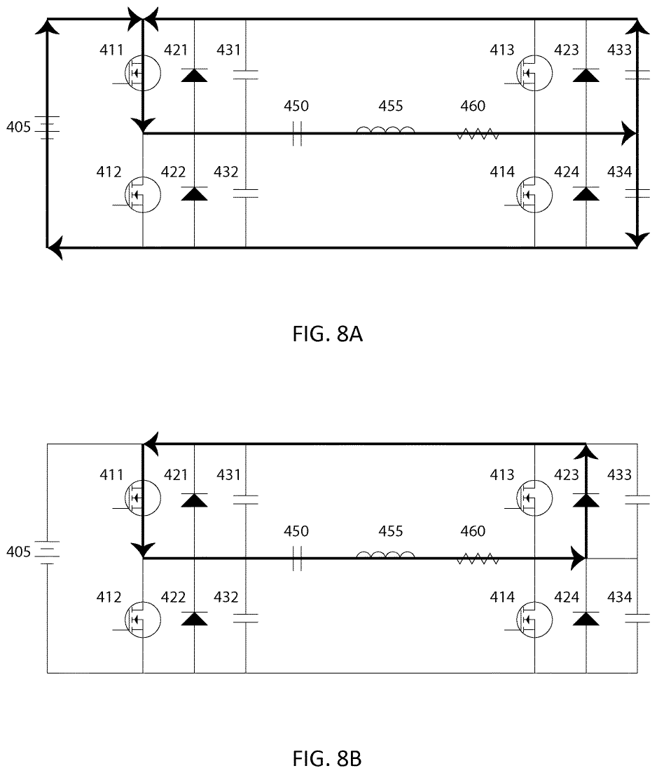

At block 502, the switches are in the following states: switch 411 is closed, switch 412 is open, switch 413 is open, and switch 414 is open. In response, capacitor 433 discharges and capacitor 434 charges as shown in FIG. 8A. After capacitor 434 charges, current flows through diode 424 as shown in FIG. 8B. This is shown in FIG. 6 as the time period 612.

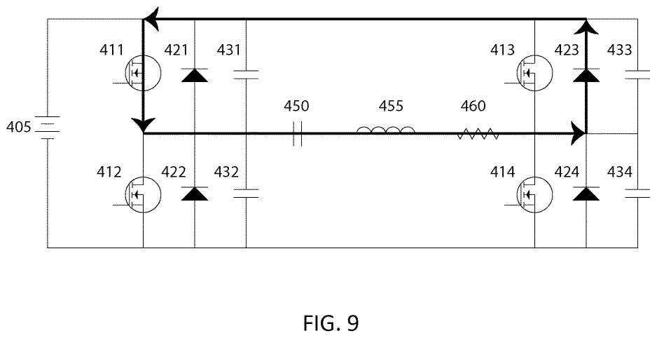

At block 503, the switches are in the following states: switch 411 is closed, switch 412 is open, switch 413 is closed, and switch 414 is open. During this phase, current flows through diode 423 as shown in FIG. 9. This is shown in FIG. 6 as the time period 613.

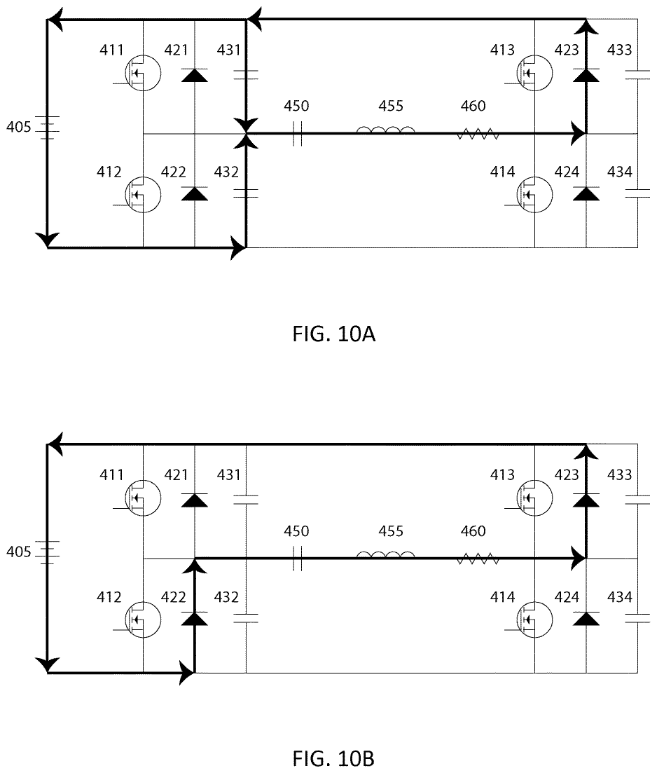

At block 504, the switches are in the following states: switch 411 is open, switch 412 is open, switch 413 is closed, and switch 414 is open. In response, capacitor 432 discharges and capacitor 431 charges as shown in FIG. 10A. After capacitor 431 charges, current flows through diode 422 as shown in FIG. 10B. This is shown in FIG. 6 as the time period 614.

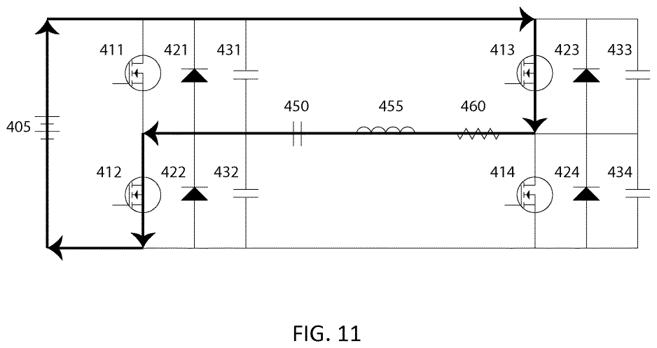

At block 505, the switches are in the following states: switch 411 is open, switch 412 is closed, switch 413 is closed, and switch 414 is open. During this phase, current flows through the load as shown in FIG. 11. This is shown in FIG. 6 as the time period 615.

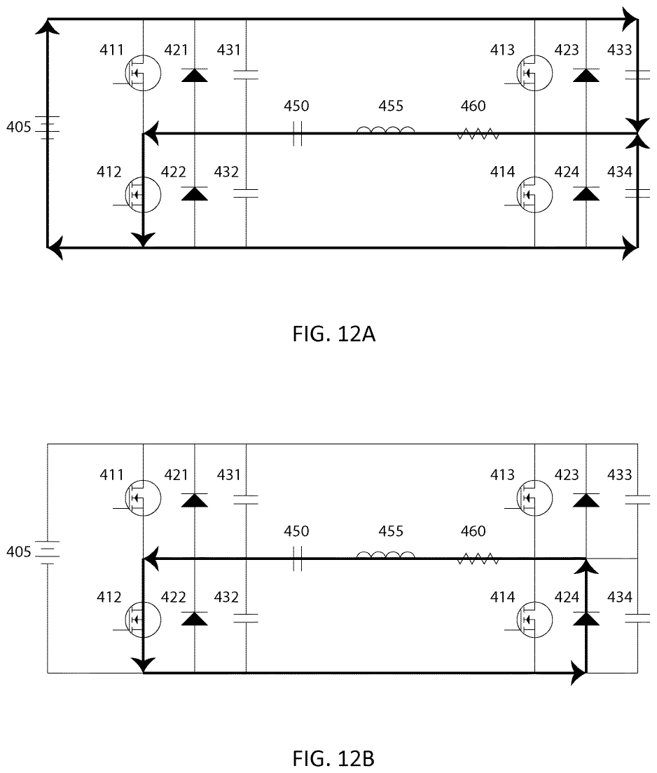

At block 506, the switches are in the following states: switch 411 is open, switch 412 is closed, switch 413 is open, and switch 414 is closed. In response, capacitor 434 discharges and capacitor 433 charges as shown in FIG. 12A. After capacitor 431 charges, current flows through diode 424 as shown in FIG. 12B. This is shown in FIG. 6 as the time period 616.

At block 507, the switches are in the following states: switch 411 is open, switch 412 is closed, switch 413 is closed, and switch 414 is closed. During this phase, current flows through the diode 424 as shown in FIG. 11. This is shown in FIG. 6 as the time period 617.

At block 508, the switches are in the following states: switch 411 is open, switch 412 is open, switch 413 is open, and switch 414 is closed. In response, capacitor 431 discharges and capacitor 432 charges as shown in FIG. 12A. After capacitor 432 charges, current flows through diode 421 as shown in FIG. 12B. This is shown in FIG. 6 as the time period 618.

As shown, in FIG. 6, switch 413 is never closed the same time as switch 414 is closed and switch 412 is never closed at the same time as switch 411.

The time between opening switch 413 and closing switch 414 and a time lag between closing switch 413 and opening switch 414. In this example, the time lag is less than 10 ns. This is shown in FIG. 6 as 612, 614, 616, and 618.

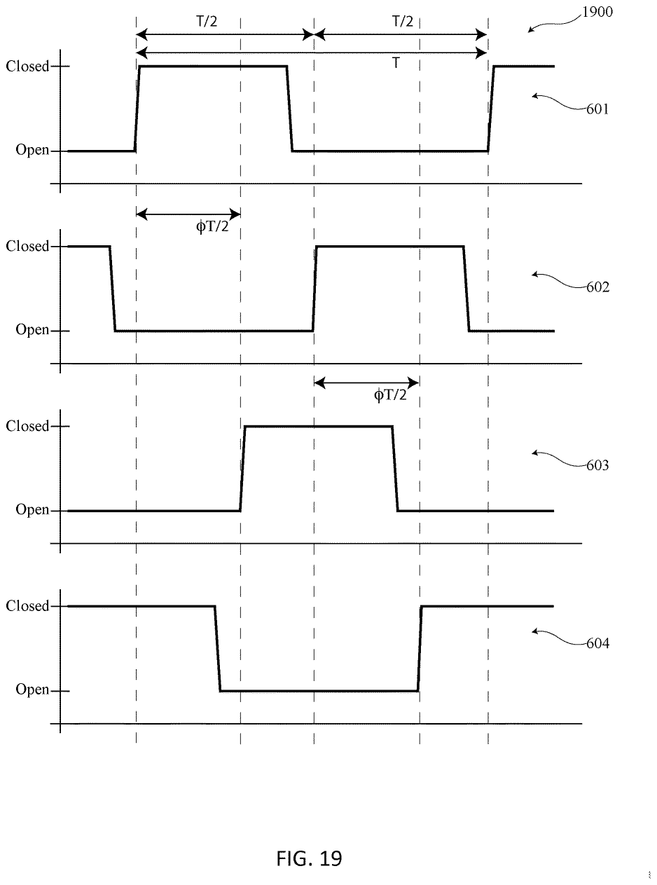

The lag can also be represented as duty cycle changes from full duty cycle (φ=1) to a reduced duty cycle (φ<1) between switch 411 and switch 413 and/or between switch 412 and 414. The time lag can be represented as Δt=φT/2, where T is a full period of control signal and/or the RF waveform as discussed in more detail in FIG. 19.

The time lag can be greater or less than this amount such as, for example, the time lag may be 0 ns, 5 ns, 10 ns, 25 ns 50 ns 100 ns 500 ns, 1,000 ns, etc.

Switch 411 is never closed when switch 412 is closed. There is a lag in time between opening switch 411 and closing switch 412 and a lag in time between closing switch 411 and opening switch 412. The time lag can be greater or less than this amount such as, for example, the time lag may be 0 ns, 5 ns, 10 ns, 25 ns 50 ns 100 ns 500 ns, 1,000 ns, etc.

The time lag, for example, may be shorter than the turn on time of any of the switches. That is time periods 612, 614, 616, and/or 618 are shorter than time periods 611, 613, 615, and/or 617. Alternatively or additionally the time periods 612, 614, 616, and/or 618 may be shorter than the pulse width of any of the pulses in waveform 601, waveform 602, waveform 603, and/or waveform 604.

The time periods 615 and 611 may be substantially the same.

The amplitude of the RF waveform to the load can be increased by increasing the time periods 611 and 615. The amplitude of the RF waveform to the load can be decreased by decreasing the time periods 611 and 615.

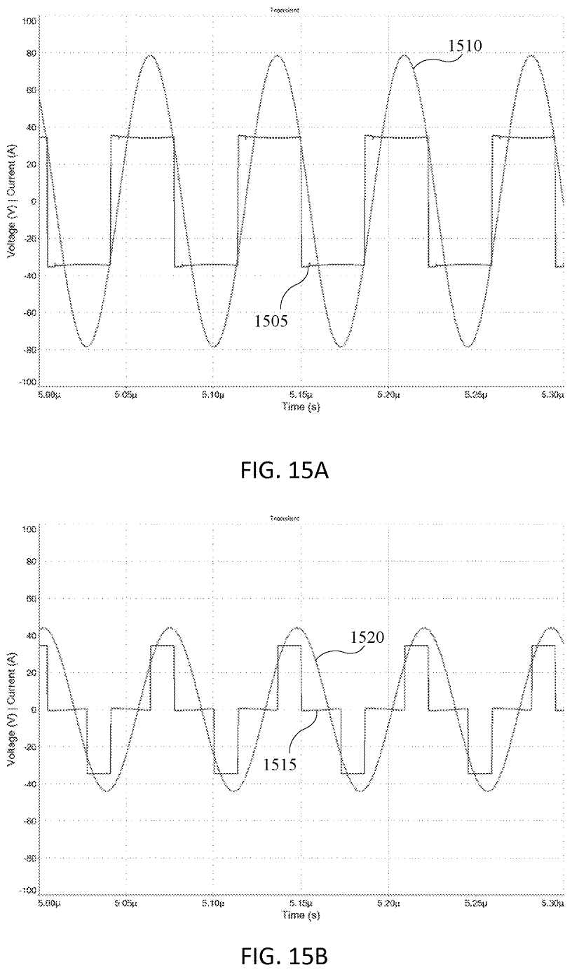

FIG. 15A and FIG. 15B show pulse width modulation to produce output pulses with lower or higher amplitudes. Such adjustments, for example, may be made on rapid timescales, where the timescales of such changes may range from 1 microsecond to 1000 seconds.

FIG. 15A shows a voltage waveform 1505 that is the voltage produced from the switches and an output current waveform 1510 that is seen on the load. In this example the RF generator switches at full duty cycle (or ø=1).

FIG. 15B shows a voltage waveform 1515 that is the voltage produced from the switches and an output current waveform 1520 that is seen on the load. In this example the switches operate at 50% duty cycle as seen in the voltage waveform 1515 (or ø=0.5). Because of this lower duty cycle, the amplitude of the output current waveform 1520 is smaller than the amplitude of the current waveform 1510.

A matchless RF generator, for example, may be used to produce plasma for various semiconductor applications such as, for example, etch, etch using capacitively coupled plasma, etch using inductively coupled plasma, deposition, ALE, remote plasma generation (RPS), etc. A matchless RF generator may be used with any plasma generation system.

A matchless RF generator has some benefits over a system that includes a matching network. The output frequency of a matchless RF generator, for example, can adjust on a timescale measured in 0.1 to 100 RF periods. A matchless RF generator, for example, can adjust its output parameters much more rapidly than a traditional matched network can. Such enhance adjustment speed may be important for controlling specific plasma processes. This may be helpful, for example, when there are changes in the plasma dynamics resulting in changes in the resonant elements. A matchless RF generator, for example, may adjust the frequency to maintain any of a number of plasma parameters such as, for example, density, chemistry, brightness, flow rate, voltage, field, etc. Such adjustments may be made in timescales of less than about 10 ns, about 10 ms or about 100 μs. Some processes may require slower changes.

The matchless generator can adjust its output on timescales ranging from 0.1% of the period of its output frequency all the way down to 1,000s of seconds. There is no limit on how slowly a matchless generator may adjust its output.

As another example, the frequency of the matchless RF generator might be changed, ramped, or modulated to induce a change, ramping, or modulation in a particular controlled plasma parameter or set of plasma parameters such as, for example, density, chemistry, brightness, flow rate, voltage, field, etc.

A matchless RF generator, for example, can operate with a frequency of about 10 kHz and 100 MHz. A single matchless RF generator can operate over a very wide range of frequencies.

Another benefit of a matchless RF generator is that it can operate over a wide range of average power and peak power conditions such as, for example, between about 10 W and 500 kW. Such different power conditions may be used in any combination to both create and sustain a plasma, and to set any number of plasma parameters.

A matchless RF generator, for example, may operate at continuous output mode. As another example, a matchless RF generator, may operate at a low duty cycle and a higher peaked power output mode. For example, when running at a given average power, the actual power might be compressed into discrete periods ranging from 0.0001% of the drive time to 99% of the dive time. For example, a matchless RF generator running at 1 kW might deliver 1 kW continuously; alternatively, a matchless RF generator running at 1 kW in bursts at 1 KHz that are 1 ms long can have a peak average power during each burst of 1 MW. Bursts may range in frequency from 1 Hz to 1 MHz, while the peak average power delivered during a burst may range from 100 W to 100 MW. A matchless RF generator, for example, can operate in a burst mode configuration where the average power of the pulser is lower than the average peak power during a burst.

A matchless RF generator, for example, may be pulsed (operated in burst mode) in a way to create various plasma effects. Burst mode can be used, for example, to maintain a certain average energy delivery rate with brief high peak power. Burst mode, for example, may involve rapidly turning the matchless system on and off, and or rapidly ramping the power/voltage/waveform up and/or down.

For example, varying both the peak power level and the burst frequency may allow for much more efficient plasma breakdown to be achieved. Short very high power bursts can be effective at producing highly repeatable and reliable plasma breakdowns/ignitions. Peak voltages, for example, may range from 500 V to 500 kV, and/or the repeatability/reliability may be well over 90%, and in some cases exceed 99.999%. Burst mode operation, for example, can allow for easy plasma formation at every burst, even if hard to break species are present and no initial seed ionization is present. Burst mode operation, for example, can eliminate the need for auxiliary pre seed or plasma pre-ionization techniques. As another example, burst mode can eliminate the need to wait for significant periods of time for the plasma to form, and/or the need to apply multiple pulses to form the plasma.

As another example, varying both the peak power level and the burst frequency may allow plasma to be formed faster and/or reach a specific target density faster. While a conventional matched system may take 100 μs to 1 ms to reach a specific plasma density, a matchless RF generator might be able to produce the same plasma density in 10 μs. A matchless RF generator, for example, can be rapidly tuned to track a rapidly changing plasma impedance. The very fast plasma formation of the matchless system can allow for a plasma to be maintained with a very low duty cycle of drive, for example less than 10% or less than 1%, so that significant quiescent time remains in between for other processes to take place during a time of quiescent plasma presence.

As another example, varying both the peak power level and the burst frequency, the matchless RF generator can drive a plasma to create a specific set of reactive species. Such reactive species may be those often employed in the semiconductor industry, and may, for example, include all combinations or F, O, N, Ar, B, Si, Cl, C and/or all their associate molecular combinations such as Si02, SiF4, NF3, CH4, etc., and/or all their associated radicals. Certain radicals may be used for chamber cleaning, ion implantation, plasma etch, and/or thin film deposition. These may be used to drive a specific chemistry across a plasma facing surface.

As another example, varying both the peak power level and the burst frequency may allow one to drive a specific chemical reaction. For example, a matchless RF generator may be used to convert Si to SiF4. As another example, the matchless RF generator, may be used to convert CH4 to H2 and C. The matchless RF generator can be used to aid in the creation of NH3.

AAs another example, operating at very high peak power for short periods of time may allow for the very efficient generation of high plasma densities. Such densities may range from 1012 to 1022 per m3. The matchless system may be operated in a way to create plasmas that are far from thermodynamic equilibrium. It may create plasmas on timescales down into the ns time range. It may create plasmas on timescales small compared to the timescales on which the plasma would flow away and disperse, and thus enable operation at much higher peak plasma densities than otherwise would be possible. Such operation allows for very high incident plasma densities and/or power density on adjoining surfaces. Operation out of thermal equilibrium is enabled.

AAs another example, a matchless RF generator operating in burst mode may allow for the plasma to be phased with respect to the waveform applied for pulsed wafer biasing; the precise delay between each wafer biasing burst can be controlled, as can the delay between each wafer biasing pulse. For example, the matchless RF generator may produce a repeating waveform pattern of a 1 ms burst of RF followed by a 1 ms burst of pulsed DC wafer bias from a DC source. Any combination of burst times and pulsed wafer bias times can be used. Any combination of delay times between the plasma created from the matchless RF generator and pulsed wafer bias. For example, delay times may range between-100 ms and 100 ms. For example, there can be long to short delays as well as partial and full overlap in waveforms. Providing such timing control can have significant benefits to optimizing an etch process. For example, the matchless RF generator may produce a high power burst just preceding the pulsed DC bias (or tailored waveform bias), so that during the time of the pulsed DC bias, a uniform IEDF can be maintained that is not perturbed by the application of the matchless RF power. There are numerous other benefits for adjusting the timing between pulsed DC bias and a matchless RF system. These include, for example, optimization and control of parameters such as etch rate, bow growth rate feature diameter, hole aspect ratio, mask erosion rate, CD, etc. Timing the delay between the matchless RF and the pulsed DC can allow for significant additional control of the underlying chemistry.

AAs another example, burst mode may not only be an on/off or all/or nothing feature. For example, burst amplitudes/frequencies/power levels/voltages, etc. can be dynamically varied from burst to burst or within each burst in a way to optimize the specific feature/parameter under consideration. This is enabled by the rapid control of a matchless RF generator, where timing decisions and actions can be made and take place at the frequency of operation. For example, from one RF period to the next, a decision can be made to either open or close a specific switch in the bridge.

As another example, a decision might be made from one RF cycle to the next to delay a specific switch or set of switches. The speed of such decision making and action may occur on timescales ranging from 0.1 RF periods to many RF periods. Such decisions and adjustments may take place much faster than matched RF generators are capable of. Matchless RF generators operate without the mechanical movement or adjustment of any resonant inductors or capacitors, and thus intrinsically can adjust on much faster timescales than standard RF matched generators can.

The matchless RF generator, for example, can be used in any number of industrial systems that use a plasma where a matchless system could be employed to great benefit given its fast and rapid tunability and/or the ability to maintain precise control over a given process.

A matchless RF generator may provide a number of control and feedback options to maintain and/or adjust specific plasma processes. For example, a matchless RF generator can regulate density, power, thermal loading, etch rate, or chemistry. The matchless RF generator, for example, can control one or more of the frequency (including how close or far the frequency is from resonance), the driving pulse width, the driving duty cycle (from 0-100%), frequency modulation, amplitude modulation, the burst frequency, the burst period, the peak power, the resonant voltage, the resonant current, the ratio of the peak power to the average power, the burst duty cycle, the drive phasing, the voltage, the peak voltage, the circulating current, the IV product, etc. Each of these parameters, for example, may be used in a process to control a specific parameter or set of parameters. Within the matchless RF generator, these parameters can be controlled by precise and specific control of the drive signals applied to the specific underlying switching elements within the RF generator.

As another example, the matchless RF generator can drive a remote plasma system, the frequency may be modulated to maintain a specific production rate of Fluorine production from NF3 in a flowing gas. As another example, the burst duty cycle and/or peak power may be set to create a reliable breakdown, followed by maintaining a steady production rate of Fluorine from a specified feed gas. Or the Fluorine concentration may be set and varied during a period of 1 ms to 10 hours to optimize the rate at which the fluorine reacts with an etch chamber, to drive a specific process.

As another example, the matchless RF generator can be used with either or both ground referenced and floating antennas without the need for a Balun or transformer. Operating a matchless system with a floating antenna may significantly reduce the parasitic coupling capacitance to ground; may enable more uniform plasma production; and may enable more reliable plasma breakdown with lower matchless system tuning requirements.

The RF generator, for example, may be a half-bridge driver or a full-bridge driver as shown in FIG. 4. The switches of the matchless RF generator, for example, may include any type of solid-state switch such as, for example, IGBTs, a MOSFETs, a SiC MOSFETs, SiC junction transistors, FETs, SiC switches, GaN switches, photoconductive switches, etc. These switches may be switched at high frequencies and/or may produce a high voltage pulses. These frequencies may, for example, include frequencies of about 400 kHz, 0.5 MHz, 2.0 MHz, 4.0 MHz, 13.56 MHz, 27.12 MHz, 40.68 MHz, 50 MHz, etc.

A matchless RF generator does not include nor does it need a traditional matching network such as, for example, a 50 ohm matching network or an external matching network or standalone matching network. Indeed, the embodiments described within this document do not require a 50 ohm matching network to tune the switching power applied to the wafer chamber. In addition, embodiments described within this document provide a variable output impedance RF generator without a traditional matching network. This can allow for rapid changes to the power drawn by the plasma chamber. Typically, this tuning of the matching network can take at least 100 μs-200 μs. In some embodiments, power changes can occur within one or two RF cycles, for example, 2.5 μs-5.0 μs at 400 kHz.

The switches of the matchless RF generator, for example, can be coupled with the primary of a transformer 1605 as shown in FIG. 16. The load may be coupled with the secondary of the transformer 1605. There is no limit to the number of different loads that may be coupled to the transformer 1605. Coupling to any and all plasma loads is envisioned.

The transformer 1605 may have a stray inductance or stray capacitance, which may be included in the one or more resonant elements that are used to determine the resonate frequency. The transformer 1605 may be coupled between the switches and the load. The transformer, for example, may comprise a transformer disclosed in U.S. patent application Ser. No. 15/365,094, titled “High Voltage Transformer,” which is incorporated into this document for all purposes.

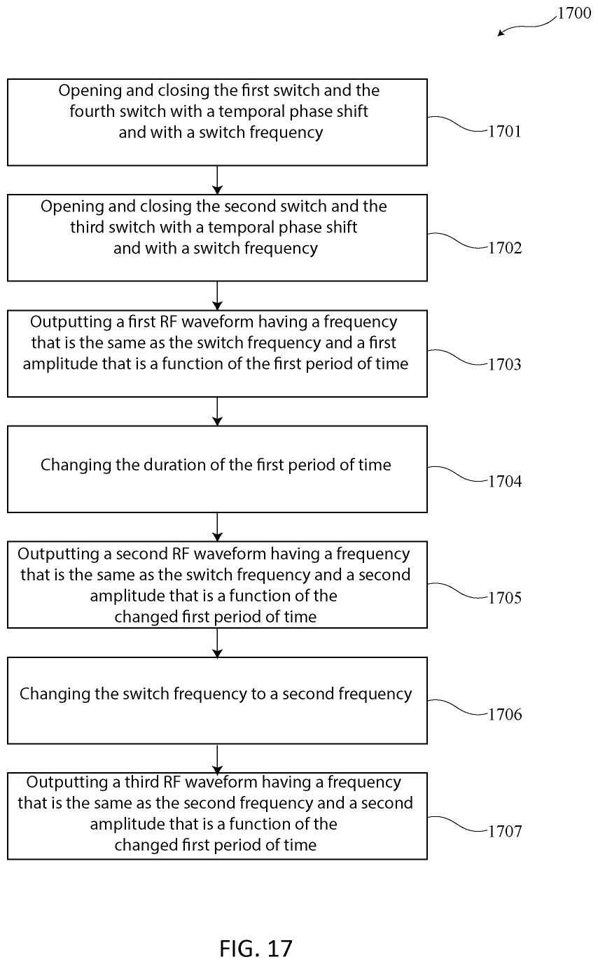

FIG. 17 is a flowchart of an example process 1700 for producing an RF waveform with a matchless RF generator.

At block 1701, opening and closing the first switch and the fourth switch with a temporal phase shift and with a switch frequency. The first switch and the fourth switch are closed for a first period of time while the second switch and the third switch are open.

At block 1702, opening and closing the second switch and the third switch with the same temporal phase shift and the with the switch frequency. The second switch and the third switch are closed for the first period of time while the first switch and the fourth switch are open.

At block 1703 a first RF waveform is output having a frequency that is the same as the switch frequency and having an amplitude that is a function of the first period of time.

At block 1704 change the duration of the first period of time.

At block 1705 a second RF waveform is output having a frequency that is the same as the switch frequency and having an amplitude that is a function of the changed first period of time.

At block 1706 the switch frequency is changed to a second frequency.

At block 1707 a third RF waveform is output having a frequency that is the same as the second frequency and having an amplitude that is a function of the changed first period of time.

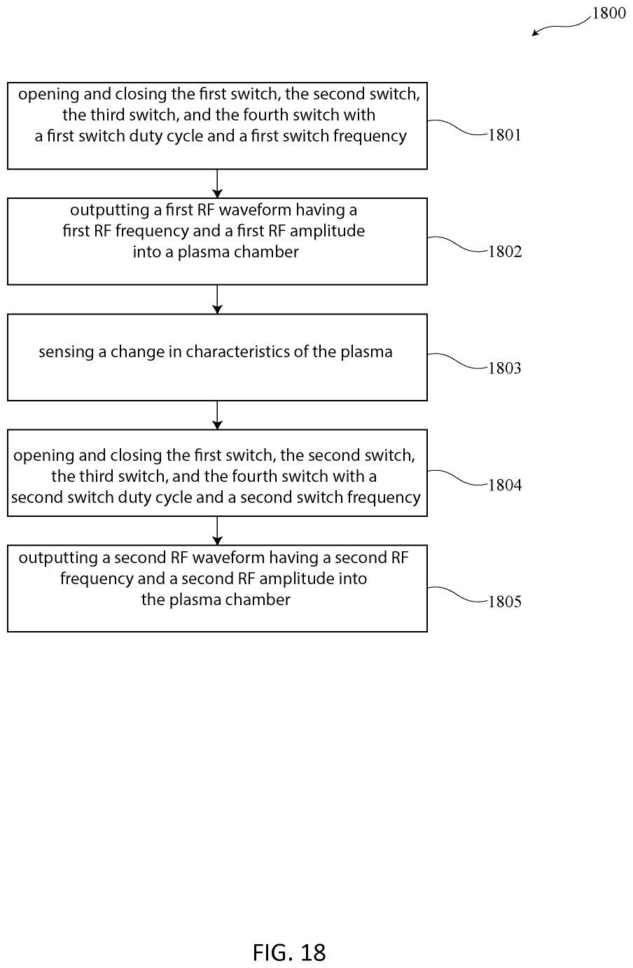

FIG. 18 is a flowchart of an example process 1800 for producing an RF waveform with a matchless RF generator.

At block 1801, opening and closing the first switch, the second switch, the third switch, and the fourth switch with a first switch duty cycle and a first switch frequency.

At block 1802, outputting a first RF waveform having a first RF frequency and a first RF amplitude into a plasma chamber.

At block 1803, sensing a change in characteristics of the plasma. The sensing, for example, can sense a change in the plasma formed within the plasma chamber: a plasma density, plasma chemistry, plasma brightness, constituent flow rate, plasma voltage, and/or plasma electric field. The sensing, for example, can sense a change in an impedance of the plasma chamber.

At block 1804, opening and closing the first switch, the second switch, the third switch, and the fourth switch with a second switch duty cycle and a second switch frequency, wherein the second duty cycle is different than the first switch duty cycle and wherein the first switch frequency is different than the second switch frequency.

At block 1805, outputting a second RF waveform having a second RF frequency and a second RF amplitude into the plasma chamber, wherein either or both the second RF frequency and the second RF amplitude are different from the first RF frequency and the first RF amplitude

FIG. 19 shows control logic for each of the switches in phase shift control with the phase control. As shown, phase control can be defined by the phase shift parameter, φ. The phase shift parameter can vary from 0≤φ≤1. The time lag in time is equal to the product of the phase shift parameter times the period divided by two: φT/2. If the phase shift parameter is zero, there is no time lag. If the phase shift parameter is 1, there is a phase shift of half a period.

Because there is a relationship between the phase and power, the phase shift control parameter can be adjusted Δφ to change the power as per the following:

$$Δ ϕ = \frac{1}{sin ( π ϕ )} ( \frac{Δ {P}_{ave}}{{P}_{ave , max}} ) ,$$

where Pₐᵥₑ is the average power, and

$${P}_{ave , max} = \frac{8}{{π}^{2}} ( \frac{{V}_{0}^{2}}{R} ) .$$

A method is disclosed for producing an RF waveform with a matchless RF generator. The method can follow the process 500.

In a first phase, closing the first switch and the fourth switch while keeping the second switch open and the third switch open.

Pausing for a first period of time.

In a second phase, keeping the first switch closed while opening the fourth switch and while keeping the second switch open and the third switch open.

Pausing for a second period of time.

In third phase, keeping the first switch closed while closing the third switch and while keeping the second switch open and the fourth switch open.

Pausing for a third period of time.

In a fourth phase, opening the first switch while keeping the third switch closed and while keeping the second switch open and the fourth switch open.

Pausing for a fourth period of time.

In a fifth phase, closing the second switch while keeping the third switch closed and while keeling the first switch open and the fourth switch open.

Pausing for a fifth period of time.

In a sixth phase, opening the third switch while keeping the second switch closed and while keeling the first switch open and the fourth switch open.

Pausing for a sixth period of time.

In a seventh phase, closing the fourth switch while keeping the second switch closed and while keeling the first switch open and the third switch open.

Pausing for a seventh period of time.

In an eighth phase, opening the second switch while keeping the fourth switch closed and while keeping the first switch open and the third switch open.

Pausing for an eighth period of time.

Outputting an RF waveform.

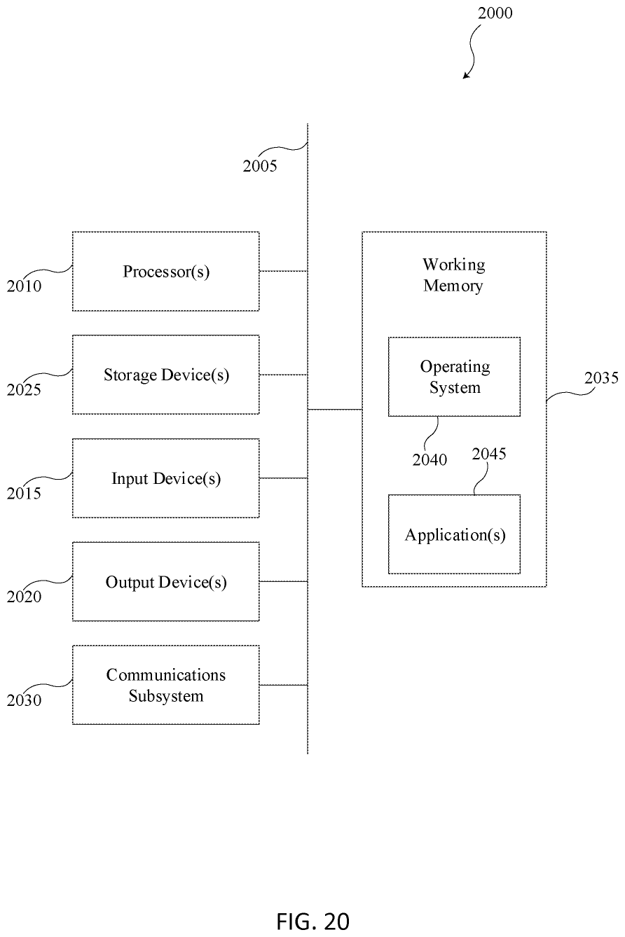

The controller 2000, shown in FIG. 20 can be used to perform any of the embodiments of the invention. For example, controller 2000 can be used to control the plurality of switches and/or execute process 500. As another example, controller 2000 can perform any calculation, identification and/or determination described here. Controller 2000 includes hardware elements that can be electrically coupled via a bus 2005 (or may otherwise be in communication, as appropriate). The hardware elements can include one or more processors 2010, including without limitation one or more general-purpose processors and/or one or more special-purpose processors (such as digital signal processing chips, graphics acceleration chips, and/or the like); one or more input devices 2015, which can include without limitation a mouse, a keyboard and/or the like; and one or more output devices 2020, which can include without limitation a display device, a printer and/or the like.

The controller 2000 may further include (and/or be in communication with) one or more storage devices 2025, which can include, without limitation, local and/or network accessible storage and/or can include, without limitation, a disk drive, a drive array, an optical storage device, a solid-state storage device, such as a random access memory (“RAM”) and/or a read-only memory (“ROM”), which can be programmable, flash-updateable and/or the like. The controller 2000 might also include a communications subsystem 2030, which can include without limitation a modem, a network card (wireless or wired), an infrared communication device, a wireless communication device and/or chipset (such as a Bluetooth device, an 802.6 device, a Wi-Fi device, cellular communication facilities, etc.), and/or the like. The communications subsystem 2030 may permit data to be exchanged with a network (such as the network described below, to name one example), and/or any other devices described in this document. In many embodiments, the controller 2000 will further include a working memory 2035, which can include a RAM or ROM device, as described above.

The controller 2000 also can include software elements, shown as being currently located within the working memory 2035, including an operating system 2040 and/or other code, such as one or more application programs 2045, which may include computer programs of the invention, and/or may be designed to implement methods of the invention and/or configure systems of the invention, as described herein. For example, one or more procedures described with respect to the method(s) discussed above might be implemented as code and/or instructions executable by a computer (and/or a processor within a computer). A set of these instructions and/or codes might be stored on a computer-readable storage medium, such as the storage device(s) 2025 described above.

In some cases, the storage medium might be incorporated within the controller 2000 or in communication with the controller 2000. In other embodiments, the storage medium might be separate from a controller 2000 (e.g., a removable medium, such as a compact disc, etc.), and/or provided in an installation package, such that the storage medium can be used to program a general-purpose computer with the instructions/code stored thereon. These instructions might take the form of executable code, which is executable by the controller 2000 and/or might take the form of source and/or installable code, which, upon compilation and/or installation on the controller 2000 (e.g., using any of a variety of generally available compilers, installation programs, compression/decompression utilities, etc.) then takes the form of executable code.

Unless otherwise specified, the term “substantially” means within 5% or 10% of the value referred to or within manufacturing tolerances. Unless otherwise specified, the term “about” means within 5% or 10% of the value referred to or within manufacturing tolerances.

The conjunction “or” is inclusive.

The terms “first”, “second”, “third”, etc. are used to distinguish respective elements and are not used to denote a particular order of those elements unless otherwise specified or order is explicitly described or required.

Numerous specific details are set forth to provide a thorough understanding of the claimed subject matter. However, those skilled in the art will understand that the claimed subject matter may be practiced without these specific details. In other instances, methods, apparatuses or systems that would be known by one of ordinary skill have not been described in detail so as not to obscure claimed subject matter.

The system or systems discussed are not limited to any particular hardware architecture or configuration. A computing device can include any suitable arrangement of components that provides a result conditioned on one or more inputs. Suitable computing devices include multipurpose microprocessor-based computer systems accessing stored software that programs or configures the computing system from a general-purpose computing apparatus to a specialized computing apparatus implementing one or more embodiments of the present subject matter. Any suitable programming, scripting, or other type of language or combinations of languages may be used to implement the teachings contained in software to be used in programming or configuring a computing device.

The use of “adapted to” or “configured to” is meant as open and inclusive language that does not foreclose devices adapted to or configured to perform additional tasks or steps. Additionally, the use of “based on” is meant to be open and inclusive, in that a process, step, calculation, or other action “based on” one or more recited conditions or values may, in practice, be based on additional conditions or values beyond those recited. Headings, lists, and numbering included are for ease of explanation only and are not meant to be limiting.

While the present subject matter has been described in detail with respect to specific embodiments thereof, it will be appreciated that those skilled in the art, upon attaining an understanding of the foregoing, may readily produce alterations to, variations of, and equivalents to such embodiments. Accordingly, it should be understood that the present disclosure has been presented for purposes of example rather than limitation, and does not preclude inclusion of such modifications, variations and/or additions to the present subject matter as would be readily apparent to one of ordinary skill in the art.

That which is claimed:

1. A plasma system comprising:
a capacitively coupled plasma chamber;
an RF generator comprising a plurality of switches that is coupled with the capacitively coupled plasma chamber, the RF generator produces a voltage waveform to the capacitively coupled plasma chamber at a frequency that is substantially similar to a resonant frequency;
resonant elements electrically coupled with the RF generator and the capacitively coupled plasma chamber, the resonant elements having a reactance; and
a controller electrically coupled with the plurality of switches and configured to control the operation of the switches to produce the voltage waveform;
wherein the resonant frequency is a function of at least the reactance and the plasma reactance;
wherein the voltage waveform has an RF amplitude and an RF frequency that is substantially the resonant frequency.

2. The plasma system according to claim 1, wherein RF waveform amplitude is greater than about 1 kV and the resonant frequency is between about 10 kHz and 100 MHz.

3. The plasma system according to claim 1, wherein RF waveform amplitude is greater than about 1 kV and the resonant frequency is a frequency is selected from the group consisting of about 400 kHz, about 13.56 MHz, and about 27 MHz.

4. The plasma system according to claim 1, wherein, wherein the switches are arranged in a full-bridge configuration.

5. The plasma system according to claim 3, wherein a subset of the plurality of switches are turned off and on out of phase.

6. The plasma system according to claim 1, wherein the RF generator is coupled with the capacitively coupled plasma chamber without a matching network.

7. The plasma system according to claim 1, wherein the RF frequency is between about 10 kHz and 100 MHz and an RF waveform amplitude greater than 100 volts.

8. The plasma system according to claim 1, wherein the RF frequency changes to a different RF frequency in less than 0.1 to 100 periods.

9. The plasma system according to claim 1, wherein the RF frequency changes in response to one or more changes in one or more of the following: a plasma density, plasma chemistry, plasma brightness, constituent flow rate, plasma voltage, and plasma electric field.

10. The plasma system according to claim 1, wherein the RF frequency changes to ensure one or more changes in one or more of the following: a constant plasma density, a constant plasma chemistry, a constant plasma brightness, a constant constituent flow rate, or a constant plasma voltage, constant power into the chamber, and a constant plasma electric field.

11. The plasma system according to claim 1, wherein the RF frequency changes to a different frequency in less than 100 μs.

12. The plasma system according to claim 1, wherein the RF generators produces an average peak power between 10 W and 500 kW.

13. The plasma system according to claim 1, wherein the output power of the RF generator changes in less than 100 μs.

14. The plasma system according to claim 1,
wherein the RF generator operates at a first frequency, a first power, and/or a first voltage to produce a plasma with a first set of reactance species;
wherein the RF generator operates at a second frequency, a second power, and/or a second voltage to produce a plasma with a second set of reactance species;
wherein the first reactance species and the second reactance species are different and are selected from the group consisting of F, O, N, Ar, B, Si, Cl, and C, and any radicals selected from the group consisting of Si02, SiF4, NF3, and CH4;
wherein the first frequency and the second frequency are different;
wherein the first voltage and the second voltage are different; and
wherein the first power and the second power are different.

15. The plasma system according to claim 1,
wherein the RF generator operates at a first frequency, a first power, and/or a first voltage to produce a plasma with a first set of reactance species from one or more molecular combinations;
wherein the RF generator operates at a second frequency, a second power, and/or a second voltage to produce a plasma with a second set of reactance species from one or more molecular combinations;
wherein the molecular combinations are selected from the group consisting of Si02, SiF4, NF3, and CH4;
wherein the first frequency and the second frequency are different;
wherein the first voltage and the second voltage are different; and
wherein the first power and the second power are different.

16. The plasma system according to claim 1, wherein the RF generator converts CH4 to H2 and C.

17. The plasma system according to claim 1, wherein the RF generator converts Si to SiF4.

18. The plasma system according to claim 1, wherein the RF generator produces NH3.

19. A method for controlling an amplitude of an RF waveform produced with a RF generator, the method comprising:
opening and closing the first switch, the second switch, the third switch, and the fourth switch with a first switch duty cycle and a first switch frequency;
outputting a first RF waveform having a first RF frequency and a first RF amplitude into a capacitively coupled plasma chamber;
sensing a change in characteristics of the plasma;
opening and closing the first switch, the second switch, the third switch, and the fourth switch with a second switch duty cycle and a second switch frequency, wherein the second duty cycle is different than the first switch duty cycle and wherein the first switch frequency is different than the second switch frequency;
outputting a second RF waveform having a second RF frequency and a second RF amplitude into the capacitively coupled plasma chamber, wherein either or both the second RF frequency and the second RF amplitude are different from the first RF frequency and the first RF amplitude.

20. The method according to claim 19, wherein sensing a change in characteristics of the plasma changer comprises sensing a change in one or more of the following: a plasma density, plasma chemistry, plasma brightness, constituent flow rate, plasma voltage, and plasma electric field.
